(19) United States
(12) Patent Application Publication
(10) Pub. No.: US 2026/0353940 A1
(43) Pub. Date: Nov. 5, 2026

(54) DISPLAY DEVICE AND MANUFACTURING METHOD THEREOF

(71) Applicant: Magnolia White Corporation, Tokyo (JP)

(72) Inventors: Nobuo IMAI, Tokyo (JP); Hiroshi OGAWA, Tokyo (JP); Yuya YAMAMOTO, Tokyo (JP)

(73) Assignee: Magnolia White Corporation, Tokyo (JP)

(21) Appl. No.: 19/745,132

(22) Filed: Jul. 17, 2026

Related U.S. Application Data
(63) Continuation of application No. 18/522,318, filed on Nov. 29, 2023.

(30) Foreign Application Priority Data
Dec. 15, 2022 (JP) 2022-200367

(51) Int. Cl. H10K 59/122; H10K 59/80; H10K 71/60

(52) U.S. Cl. CPC H10K 59/122; H10K 59/80521; H10K 59/8722; H10K 71/60

(57) ABSTRACT

According to one embodiment, a display device includes a lower electrode, a rib including a pixel aperture, a partition which includes a conductive bottom portion on the rib, a stem portion on the bottom portion, and a top portion on the stem portion, an organic layer which covers the lower electrode through the pixel aperture, and an upper electrode which covers the organic layer and is in contact with the bottom portion. The bottom portion and the top portion protrude from a side surface of the stem portion. A first protrusion length of the bottom portion from the side surface is greater than or equal to 0.2 μm and less than or equal to 0.7 μm.

### CROSS-REFERENCE TO RELATED APPLICATIONS

This application is a continuation of U.S. application Ser. No. 18/522,318, filed Nov. 29, 2023, which is based upon and claims the benefit of priority from Japanese Patent Application No. 2022-200367, filed Dec. 15, 2022, the entire contents of each are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer.

When such a display device is manufactured, a technique which improves the yield is required.

### BRIEF DESCRIPTION OF THE DRAWINGS

FIG. 1 is a diagram showing a configuration example of a display device according to an embodiment.

FIG. 2 is a schematic plan view showing an example of the layout of subpixels.

FIG. 3 is a schematic cross-sectional view of the display device along the III-III line of FIG. 2.

FIG. 4 is a schematic cross-sectional view showing an example of a configuration which could be applied to a partition.

FIG. 5 is a flowchart showing an example of the manufacturing method of the display device.

FIG. 6 is a schematic cross-sectional view showing an example of a process for forming a rib and the partition.

FIG. 7 is a schematic cross-sectional view showing a process following FIG. 6.

FIG. 8 is a schematic cross-sectional view showing a process following FIG. 7.

FIG. 9 is a schematic cross-sectional view showing a process following FIG. 8.

FIG. 10 is a schematic cross-sectional view showing a process following FIG. 9.

FIG. 11 is a schematic cross-sectional view showing a process following FIG. 10.

FIG. 12 is a schematic cross-sectional view showing a process following FIG. 11.

FIG. 13 is a schematic cross-sectional view showing an example of a process for forming display elements.

FIG. 14 is a schematic cross-sectional view showing a process following FIG. 13.

FIG. 15 is a schematic cross-sectional view showing a process following FIG. 14.

FIG. 16 is a schematic cross-sectional view showing a process following FIG. 15.

FIG. 17 is a schematic cross-sectional view showing a process following FIG. 16.

FIG. 18 is a schematic cross-sectional view showing a process following FIG. 17.

### DETAILED DESCRIPTION

In general, according to one embodiment, a display device comprises a lower electrode, a rib comprising a pixel aperture which overlaps the lower electrode, a partition which includes a conductive bottom portion provided on the rib, a stem portion provided on the bottom portion, and a top portion provided on the stem portion, an organic layer which covers the lower electrode through the pixel aperture and emits light based on application of voltage, and an upper electrode which covers the organic layer and is in contact with the bottom portion. The bottom portion and the top portion protrude from a side surface of the stem portion. A first protrusion length of the bottom portion from the side surface is greater than or equal to 0.2 μm and less than or equal to 0.7 μm.

According to another embodiment, a manufacturing method of a display device includes forming a lower electrode, forming a rib which covers at least part of the lower electrode, and forming a partition on the rib. The partition includes a conductive bottom portion, a stem portion located on the bottom portion and a top portion located on the stem portion. The forming the partition includes forming a conductive first layer, forming a second layer on the first layer, forming a third layer on the second layer, forming a resist on the third layer, forming the top portion by removing a portion of the third layer exposed from the resist, removing a portion of the second layer exposed from the top portion, decreasing a width of the second layer which remains under the top portion to a first width which is less than a width of the top portion, forming the bottom portion by removing a portion of the first layer exposed from the second layer and having the first width, and forming the stem portion by decreasing the width of the second layer to a second width which is less than a width of the bottom portion after forming the bottom portion.

These configurations can improve the yield of a display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. The third direction Z is a normal direction relative to a plane including the first direction X and the second direction Y. When various elements are viewed parallel to the third direction Z, the appearance is defined as a plan view.

The display device of the present embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

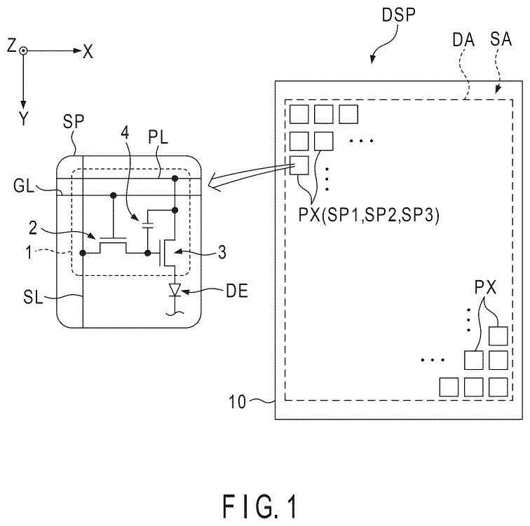

FIG. 1 is a diagram showing a configuration example of a display device DSP according to an embodiment. The display device DSP comprises a display area DA which displays an image and a surrounding area SA around the display area DA on an insulating substrate 10. The substrate 10 may be glass or a resinous film having flexibility.

In the present embodiment, the substrate 10 is rectangular as seen in plan view. It should be noted that the shape of the substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes a blue subpixel SP1, a green subpixel SP2 and a red subpixel SP3. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

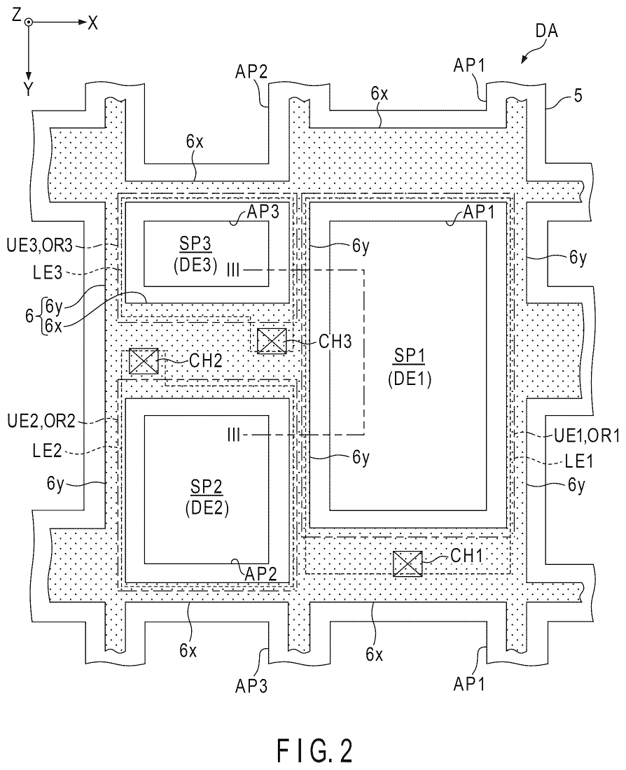

FIG. 2 is a schematic plan view showing an example of the layout of subpixels SP1, SP2 and SP3. In the example of FIG. 2, each of subpixels SP2 and SP3 is adjacent to subpixel SP1 in the first direction X. Further, subpixels SP2 and SP3 are arranged in the second direction Y.

When subpixels SP1, SP2 and SP3 are provided in line with this layout, in the display area DA, a column in which subpixels SP2 and SP3 are alternately provided in the second direction Y and a column in which a plurality of subpixels SP1 are repeatedly provided in the second direction Y are formed. These columns are alternately arranged in the first direction X. It should be noted that the layout of subpixels SP1, SP2 and SP3 is not limited to the example of FIG. 2.

A rib 5 and a partition 6 are provided in the display area DA. The rib 5 comprises pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3.

The partition 6 is provided in the boundary between adjacent subpixels SP and overlaps the rib 5 as seen in plan view. The partition 6 comprises a plurality of first partitions 6x extending in the first direction X and a plurality of second partitions 6y extending in the second direction Y. The first partitions 6x are provided between two pixel apertures AP1 which are adjacent to each other in the second direction Y and between the pixel apertures AP2 and AP3 which are adjacent to each other in the second diction Y. Each second partition 6y is provided between the pixel apertures AP1 and AP2 which are adjacent to each other in the first direction X and between the pixel apertures AP1 and AP3 which are adjacent to each other in the first direction X.

In the example of FIG. 2, the first partitions 6x and the second partitions 6y are connected to each other. In this configuration, the partition 6 has a grating shape surrounding the pixel apertures AP1, AP2 and AP3 as a whole. In other words, the partition 6 comprises apertures in subpixels SP1, SP2 and SP3 in a manner similar to that of the rib 5.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib 5 and the partition 6 surround each of these display elements DE1, DE2 and DE3.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3. In the example of FIG. 2, the contact holes CH1, CH2 and CH3 overlap the rib 5 and the partition 6 as a whole. However, the configuration is not limited to this example.

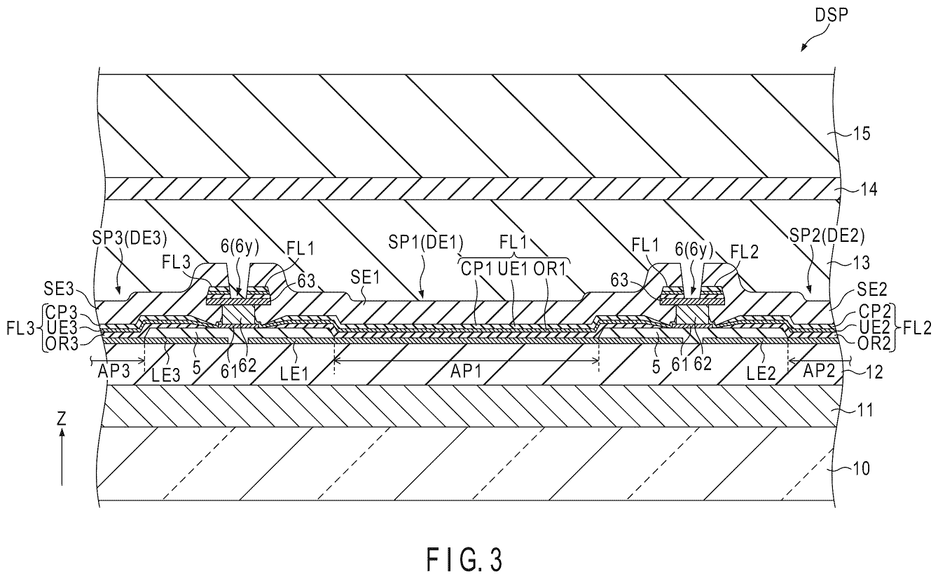

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, scanning line GL, signal line SL and power line PL shown in FIG. 1.

The circuit layer 11 is covered with an insulating layer 12. The insulating layer 12 functions as a planarization film which planarizes the irregularities formed by the circuit layer 11. Although not shown in the section of FIG. 3, the contact holes CH1, CH2 and CH3 described above are provided in the insulating layer 12.

The lower electrodes LE1, LE2 and LE3 are provided on the insulating layer 12. The rib 5 is provided on the insulating layer 12 and the lower electrodes LE1, LE2 and LE3. The end portions of the lower electrodes LE1, LE2 and LE3 are covered with the rib 5.

The partition 6 comprises a bottom portion 61 provided on the rib 5, a stem portion 62 provided on the bottom portion 61 and a top portion 63 provided on the stem portion 62. The top portion 63 has a width greater than that of the stem portion 62. By this configuration, in FIG. 3, the both end portions of the top portion 63 protrude relative to the side surfaces of the stem portion 62. This shape of the partition 6 is called an overhang shape.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3.

In the example of FIG. 3, a cap layer CP1 is provided on the upper electrode UE1. A cap layer CP2 is provided on the upper electrode UE2. A cap layer CP3 is provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a stacked layer body including the organic layer OR1, the upper electrode UE1 and the cap layer CP1 is called a thin film FL1. A stacked layer body including the organic layer OR2, the upper electrode UE2 and the cap layer CP2 is called a thin film FL2. A stacked layer body including the organic layer OR3, the upper electrode UE3 and the cap layer CP3 is called a thin film FL3.

The thin film FL1 is partly located on the top portion 63. This portion is spaced apart from, of the thin film FL1, the portion located under the partition 6 (in other words, the portion which constitutes the display element DE1). Similarly, the thin film FL2 is partly located on the top portion 63. This portion is spaced apart from, of the thin film FL2, the portion located under the partition 6 (in other words, the portion which constitutes the display element DE2). Further, the thin film FL3 is partly located on the top portion 63. This portion is spaced apart from, of the thin film FL3, the portion located under the partition 6 (in other words, the portion which constitutes the display element DE3).

Sealing layers SE1, SE2 and SE3 are provided in subpixels SP1, SP2 and SP3, respectively. The sealing layer SE1 continuously covers the thin film FL1 and the partition 6 around subpixel SP1. The sealing layer SE2 continuously covers the thin film FL2 and the partition 6 around subpixel SP2. The sealing layer SE3 continuously covers the thin film FL3 and the partition 6 around subpixel SP3.

In the example of FIG. 3, the thin film FL1 and sealing layer SE1 located on the partition 6 between subpixels SP1 and SP2 are spaced apart from the thin film FL2 and sealing layer SE2 located on this partition 6. The thin film FL1 and sealing layer SE1 located on the partition 6 between subpixels SP1 and SP3 are spaced apart from the thin film FL3 and sealing layer SE3 located on this partition 6.

The sealing layers SE1, SE2 and SE3 are covered with a resin layer 13. The resin layer 13 is covered with a sealing layer 14. The sealing layer 14 is covered with a resin layer 15. The resin layers 13 and 15 and the sealing layer 14 are continuously provided in at least the entire display area DA and partly extend in the surrounding area SA as well.

A cover member such as a polarizer, a touch panel, a protective film or a cover glass may be further provided above the resin layer 15. This cover member may be attached to the resin layer 15 via, for example, an adhesive layer such as an optical clear adhesive (OCA).

The insulating layer 12 is formed of an organic insulating material. Each of the rib 5 and the sealing layers 14, SE1, SE2 and SE3 can be formed of an inorganic insulating material such as silicon nitride (SiN), silicon oxide (SiO), silicon oxynitride (SiON) or aluminum oxide (Al₂O₃). Each of the rib 5 and the sealing layers 14, SE1, SE2 and SE3 may comprise a single-layer structure formed of one of the inorganic insulating materials, or may comprise a stacked structure in which the layers of two or more types of inorganic insulating materials are stacked. The inorganic insulating materials of the rib 5 and the sealing layers 14, SE1, SE2 and SE3 may be the same as each other or different from each other. For example, the rib 5 is formed of silicon oxynitride, and each of the sealing layers 14, SE1, SE2 and SE3 is formed of silicon nitride.

Each of the resin layers 13 and 15 is formed of, for example, a resinous material (organic insulating material) such as epoxy resin or acrylic resin. Each of the lower electrodes LE1, LE2 and LE3 comprises a reflective layer formed of, for example, silver (Ag), and a pair of conductive oxide layers covering the upper and lower surfaces of the reflective layer. Each conductive oxide layer can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

For example, each of the organic layers OR1, OR2 and OR3 comprises a stacked structure consisting of a hole injection layer, a hole transport layer, an electron blocking layer, a light emitting layer, a hole blocking layer, an electron transport layer and an electron injection layer. Each of the organic layers OR1, OR2 and OR3 may comprise a tandem structure including a plurality of light emitting layers.

Each of the cap layers CP1, CP2 and CP3 is formed of, for example, a multilayer body of a plurality of transparent thin films. As the thin films, the multilayer body may include a thin film formed of an inorganic material and a thin film formed of an organic material. These thin films have refractive indices different from each other. The materials of the thin films constituting the multilayer body are different from the materials of the upper electrodes UE1, UE2 and UE3 and are also different from the materials of the sealing layers SE1, SE2 and SE3. It should be noted that at least one of the cap layers CP1, CP2 and CP3 may be omitted.

The bottom portion 61 can be formed of, for example, a conductive material such as titanium (Ti), titanium nitride (TiN), molybdenum (Mo), tungsten (W), a molybdenum-tungsten alloy (MoW), a molybdenum-niobium alloy (MoNb), ITO or IZO. The bottom portion 61 may comprise a single-layer structure formed of one of these materials or may comprise a stacked structure including a plurality of layers formed of different materials.

The stem portion 62 can be formed of, for example, aluminum (Al). The stem portion 62 may be formed of an aluminum alloy. For the aluminum alloy, for example, an aluminum-neodymium alloy (AlNd), an aluminum-yttrium alloy (AlY) or an aluminum-silicon alloy (AlSi) could be used. The stem portion 62 may comprise a single-layer structure formed of aluminum or an aluminum alloy or may comprise a stacked structure including a plurality of layers formed of different materials. The stem portion 62 may include a layer formed of an insulating material such as silicon nitride, silicon oxide or silicon oxynitride.

The top portion 63 can be formed of, for example, a conductive material such as titanium, titanium nitride, molybdenum, tungsten, a molybdenum-tungsten alloy, a molybdenum-niobium alloy, ITO or IZO. The top portion 63 may comprise a single-layer structure formed of one of these materials or may comprise a stacked structure including a plurality of layers formed of different materials. The top portion 63 may include a layer formed of an insulating material such as silicon nitride, silicon oxide or silicon oxynitride.

The upper electrodes UE1, UE2 and UE3 are in contact with the bottom portions 61. Common voltage is applied to the bottom portions 61. This common voltage is applied to each of the upper electrodes UE1, UE2 and UE3. Pixel voltage is applied to the lower electrodes LE1, LE2 and LE3 through the pixel circuits 1 provided in subpixels SP1, SP2 and SP3, respectively.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

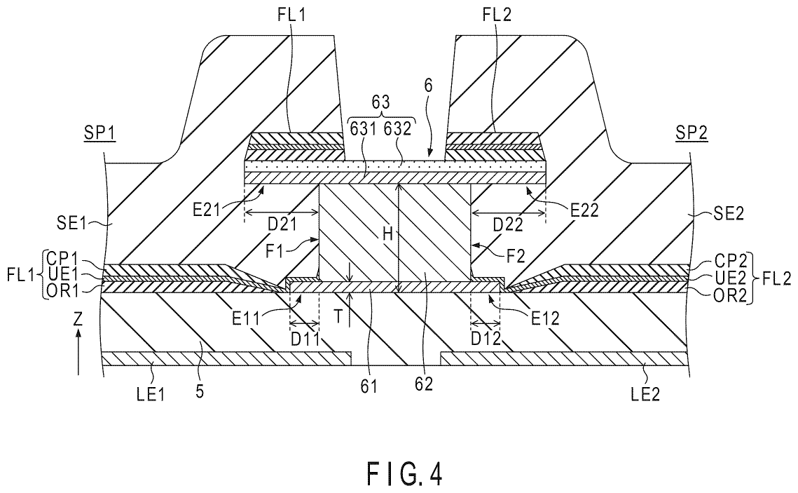

FIG. 4 is a schematic cross-sectional view showing an example of a configuration which could be applied to the partition 6. Here, this specification shows the portion located between subpixels SP1 and SP2 in the partition 6 as an example. A structure similar to that of FIG. 4 could be also applied to, in the partition 6, the portion located between subpixels SP1 and SP3 and the portion located between subpixels SP2 and SP3.

In the example of FIG. 4, each of the bottom portion 61 and the stem portion 62 comprises a single-layer structure. The top portion 63 comprises a first top layer 631, and a second top layer 632 provided on the first top layer 631. The materials of the first top layer 631 and the second top layer 632 could be appropriately selected from the materials of the top portion 63 described above. The bottom portion 61 and the top portion 63 are formed so as to be thinner than the stem portion 62.

The stem portion 62 comprises a side surface F1 on the subpixel SP1 side and a side surface F2 on the subpixel SP2 side. The bottom portion 61 and the top portion 63 protrude from the side surfaces F1 and F2. Specifically, the bottom portion 61 comprises an end portion E11 which protrudes from the side surface F1 and an end portion E12 which protrudes from the side surface F2. The top portion 63 comprises an end portion E21 which protrudes from the side surface F1 and an end portion E22 which protrudes from the side surface F2.

The end portion E11 is spaced apart from the organic layer OR1 and is covered with the upper electrode UE1. The end portion E12 is spaced apart from the organic layer OR2 and is covered with the upper electrode UE2. In the example of FIG. 4, the upper electrode UE1 is in contact with part of the side surface F1, and the upper electrode UE2 is in contact with part of the side surface F2. The configuration is not limited to this example. The upper electrode UE1 or UE2 may not be in contact with the side surface F1 or F2.

Here, the protrusion length of the bottom portion 61 from the side surface F1 is defined as D11. The protrusion length of the bottom portion 61 from the side surface F2 is defined as D12. The protrusion length of the top portion 63 from the side surface F1 is defined as D21. The protrusion length of the top portion 63 from the side surface F2 is defined as D22. The thickness of the bottom portion 61 is defined as T. The height from the upper surface of the rib 5 to the top portion 63 is defined as H.

Protrusion lengths D11, D12, D21 and D22 correspond to the widths of the end portions E11, E12, E21 and E22, respectively. Height H corresponds to the total thickness of the bottom portion 61 and the stem portion 62. For example, protrusion lengths D11 and D12 are equal to each other, and protrusion lengths D21 and D22 are equal to each other. However, protrusion lengths D11 and D12 may be different from each other. Further, protrusion lengths D21 and D22 may be different from each other.

Thickness T is sufficiently less than height H (T<H). For example, both protrusion length D11 and protrusion D12 are greater than thickness T (D11, D12>T). Protrusion length D11 is less than protrusion length D21 (D11<D21). Protrusion length D12 is less than protrusion length D22 (D12<D22).

For example, thickness T is 20 nm. Each of protrusion lengths D11 and D12 is, for example, greater than or equal to 0.2 μm and less than or equal to 0.7 μm. Each of protrusion lengths D11 and D12 may be greater than or equal to 0.3 μm and less than or equal to 0.5 μm.

It should be noted that the configuration of the partition 6 shown in FIG. 4 is merely an example. Each of the bottom portion 61 and the stem portion 62 may comprise a stacked structure consisting of two or more layers. The top portion 63 may comprise a single-layer structure or may comprise a stacked structure consisting of three or more layers.

Now, this specification explains the manufacturing method of the display device DSP with reference to an example in which the partition 6 comprises the configuration shown in FIG. 4. Here, for example, this specification assumes a case where the rib 5 is formed of silicon oxynitride, and the bottom portion 61 is formed of titanium nitride, and the stem portion 62 is formed of aluminum, and the first top layer 631 is formed of titanium, and the second top layer 632 is formed of ITO.

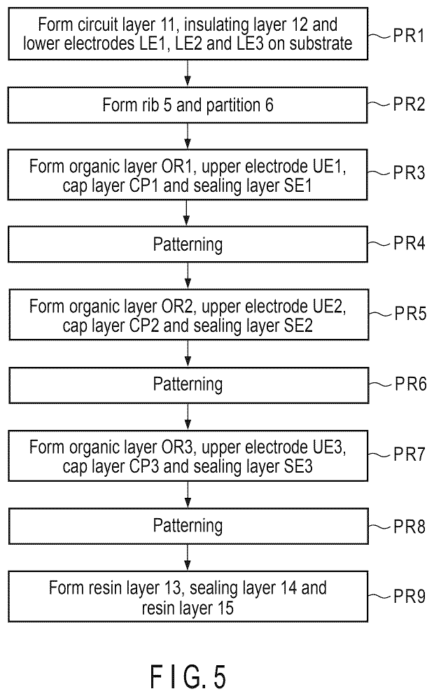

FIG. 5 is a flowchart showing an example of the manufacturing method of the display device DSP. To manufacture the display device DSP, first, the circuit layer 11, the insulating layer 12 and the lower electrodes LE1, LE2 and LE3 are formed on the substrate 10 (process PR1). Further, the rib 5 and the partition 6 are formed (process PR2).

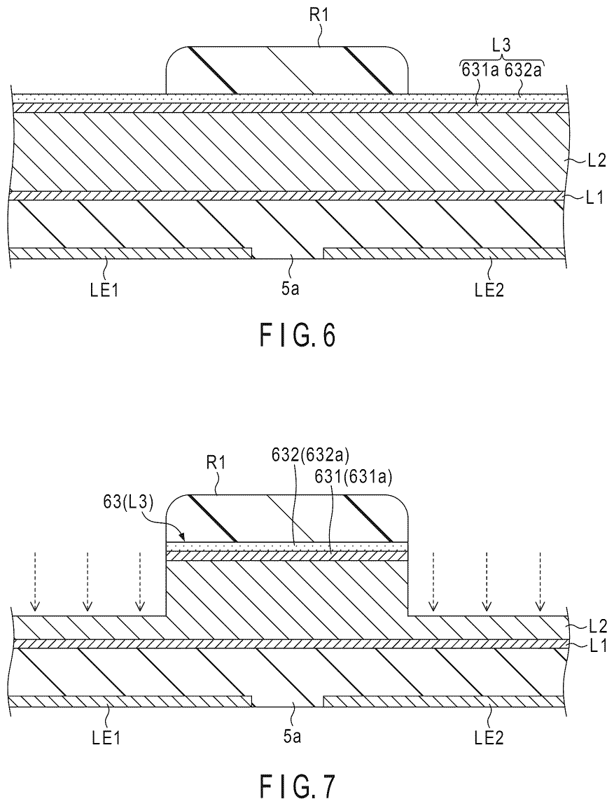

FIG. 6 to FIG. 12 are schematic cross-sectional views showing an example of process PR2 for forming the rib 5 and the partition 6. In these figures, the substrate 10, the circuit layer 11 and the insulating layer 12 are omitted.

In process PR2, as shown in FIG. 6, an insulating layer 5a which is processed so as to be the rib 5 is formed. A first layer L1 which is processed so as to be the bottom portion 61 is formed on the insulating layer 5a. A second layer L2 which is processed so as to be the stem portion 62 is formed on the first layer L1. A third layer L3 which is processed so as to be the top portion 63 is formed on the second layer L2. Further, a resist R1 patterned into the planar shape of the partition 6 is formed on the third layer L3. The third layer L3 includes a first top layer 631a, and a second top layer 632a which covers the first top layer 631a. In this example, the insulating layer 5a is formed of silicon oxynitride. The first layer L1 is formed of titanium nitride. The second layer L2 is formed of aluminum. The first top layer 631a is formed of titanium. The second top layer 632a is formed of ITO.

Subsequently, as shown in FIG. 7, of the second top layer 632a, the portion exposed from the resist R1 is removed by wet etching. Further, of the first top layer 631a, the portion exposed from the resist R1 is removed by anisotropic dry etching. By these etching processes, the top portion 63 including the first top layer 631 and the second top layer 632 is formed.

In the anisotropic dry etching described above, the thickness of, of the second layer L2, the portion exposed from the resist R1 and the top portion 63 is also reduced. It should be noted that the configuration is not limited to this example. Of the second layer L2, the portion exposed from the resist R1 may be entirely removed. Further, the processes of the first top layer 631a and the second layer L2 shown in FIG. 7 may be performed by different types of etching.

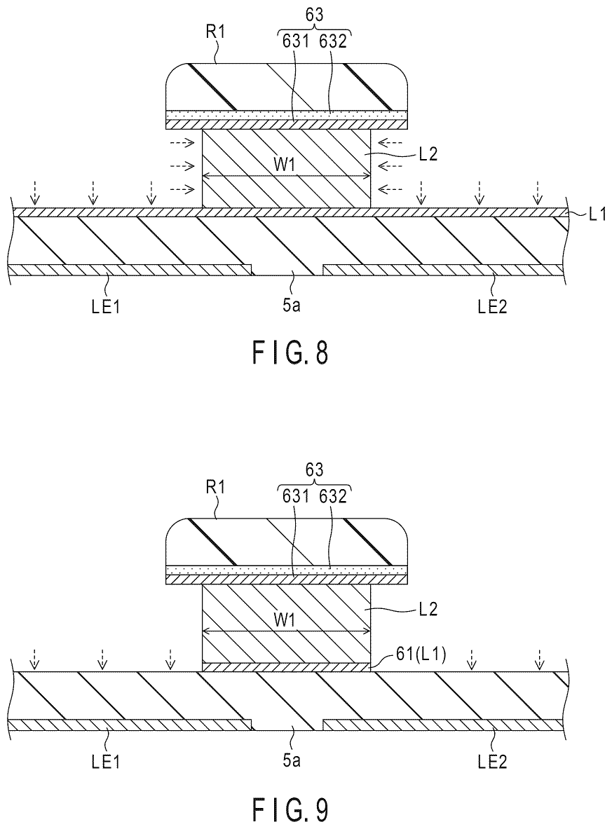

After the process of FIG. 7, as shown in FIG. 8, the second layer L2 is processed by isotropic wet etching (first wet etching). In this wet etching, of the second layer L2, the portion in which the thickness is reduced in the process of FIG. 7 is removed. Further, the width of the second layer L2 which remains under the top portion 63 is decreased to a first width W1 which is less than the width of the top portion 63.

After the process of FIG. 8, as shown in FIG. 9, of the first layer L1, the portion exposed from the second layer L2 is removed by dry etching. By this process, the bottom portion 61 having the first width W1 is formed.

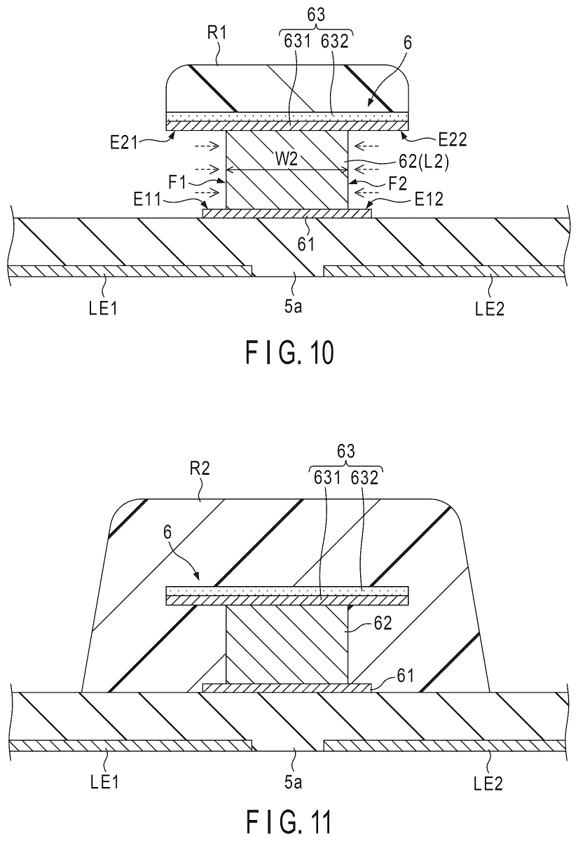

After the process of FIG. 9, isotropic wet etching is performed again (second wet etching). By this process, as shown in FIG. 10, the width of the second layer L2 is decreased to a second width W2 which is less than the width of the bottom portion 61. In this manner, the stem portion 62 is formed.

In the partition 6 formed through the above process, as shown in FIG. 4, the end portions E11 and E12 of the bottom portion 61 protrude from the side surfaces F1 and F2 of the stem portion 62. Moreover, the end portions E21 and E22 of the top portion 63 protrude from the side surfaces F1 and F2. After the formation of the partition 6, the resist R1 is removed.

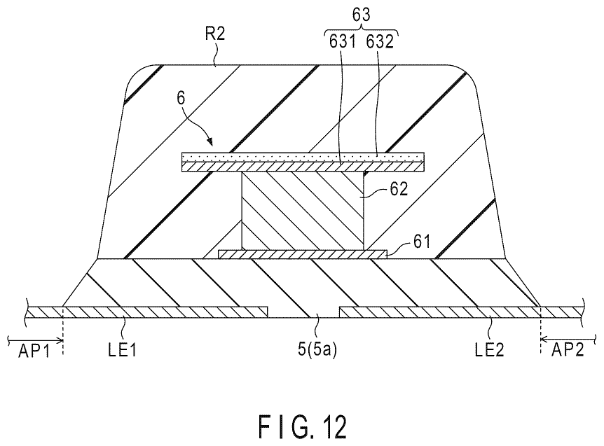

Subsequently, as shown in FIG. 11, a resist R2 patterned into the planar shape of the rib 5 is provided. Further, as shown in FIG. 12, of the insulating layer 5a, the portion exposed from the resist R2 is removed by dry etching. By this process, the rib 5 comprising the pixel apertures AP1, AP2 and AP3 is formed. After this dry etching, the resist R2 is removed.

In the example of FIG. 6 to FIG. 12, the pixel apertures AP1, AP2 and AP3 of the rib 5 are formed after the formation of the partition 6. As another example, the partition 6 may be formed after the formation of the pixel apertures AP1, AP2 and AP3. The processes for forming the first layer L1, the second layer L2, the third layer L3 and the rib 5, such as the wet etching and dry etching described here as examples, could be appropriately modified depending on the materials of these portions.

After the formation of the rib 5 and the partition 6, a process for forming the display elements DE1, DE2 and DE3 is performed. In the embodiment, this specification assumes a case where the display element DE1 is formed firstly, and the display element DE2 is formed secondly, and the display element DE3 is formed lastly. It should be noted that the formation order of the display elements DE1, DE2 and DE3 is not limited to this example.

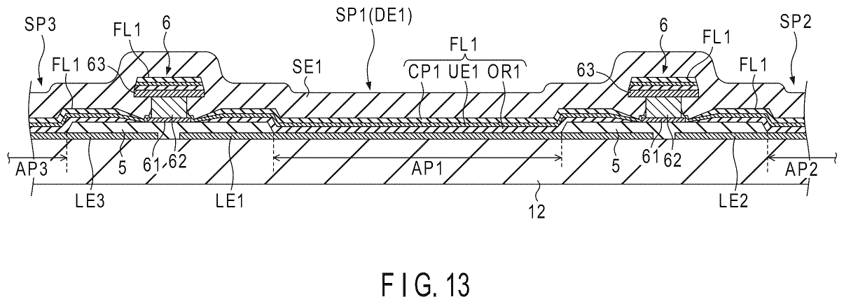

FIG. 13 to FIG. 18 are schematic cross-sectional views showing an example of a process for forming the display elements DE1, DE2 and DE3. To form the display element DE1, first, as shown in FIG. 13, the organic layer OR1 which covers the lower electrode LE1 through the pixel aperture AP1, the upper electrode UE1 which covers the organic layer OR1 and is in contact with the bottom portion 61 and the cap layer CP1 which covers the upper electrode UE1 are formed in order by vapor deposition, and further, the sealing layer SE1 which continuously covers the cap layer CP1 and the partition 6 is formed by chemical vapor deposition (CVD) (process PR3).

The thin film FL1 including the organic layer OR1, the upper electrode UE1 and the cap layer CP1 is formed in at least the entire display area DA, is provided in subpixels SP2 and SP3 as well as subpixel SP1 and is also provided on the partition 6. The thin film FL1 is divided by the partition 6 having an overhang shape. The sealing layer SE1 is formed in the entire display area DA and continuously covers the thin film FL1 and the partition 6 without being divided by the partition 6.

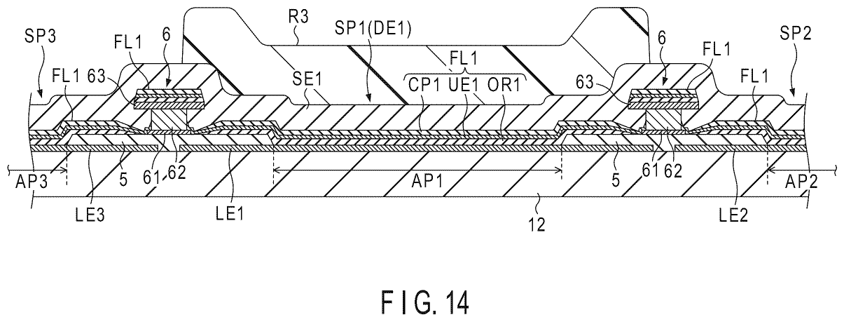

After process PR3, the thin film FL1 and the sealing layer SE1 are patterned (process PR4). In this patterning, as shown in FIG. 14, a resist R3 is provided on the sealing layer SE1. The resist R3 is located above subpixel SP1 and part of the partition 6 around subpixel SP1.

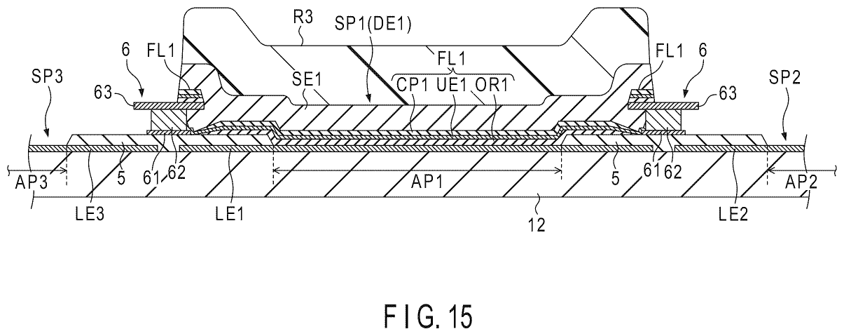

Subsequently, as shown in FIG. 15, of the thin film FL1 and the sealing layer SE1, the portions exposed from the resist R3 are removed by etching using the resist R3 as a mask. For example, this etching includes wet etching and dry etching processes which are performed in order for the sealing layer SE1, the cap layer CP1, the upper electrode UE1 and the organic layer OR1.

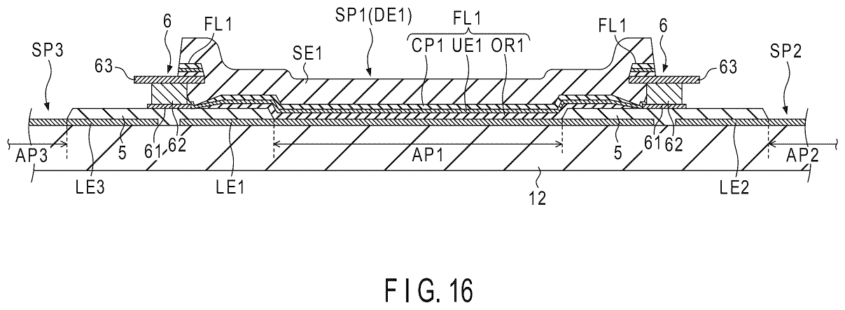

After the process shown in FIG. 15, the resist R3 is removed. This process allows the acquisition of the following substrate. As shown in FIG. 16, in the substrate, the display element DE1 and the sealing layer SE1 are formed in subpixel SP1, and neither a display element nor a sealing layer is formed in subpixel SP2 or subpixel SP3.

The display element DE2 is formed by a procedure similar to that of the display element DE1. Specifically, after process PR4, the organic layer OR2 which covers the lower electrode LE2 through the pixel aperture AP2, the upper electrode UE2 which covers the organic layer OR2 and the cap layer CP2 which covers the upper electrode UE2 are formed in order by vapor deposition, and further, the sealing layer SE2 which continuously covers the cap layer CP2 and the partition 6 is formed by CVD (process PR5).

The thin film FL2 including the organic layer OR2, the upper electrode UE2 and the cap layer CP2 is formed in at least the entire display area DA, is provided in subpixels SP1 and SP3 as well as subpixel SP2 and is also provided on the partition 6. The thin film FL2 is divided by the partition 6 having an overhang shape. The sealing layer SE2 is formed in the entire display area DA and continuously covers the thin film FL2 and the partition 6 without being divided by the partition 6.

After process PR5, the thin film FL2 and the sealing layer SE2 are patterned by wet etching and dry etching (process PR6). The flow of this patterning is similar to that of process PR4.

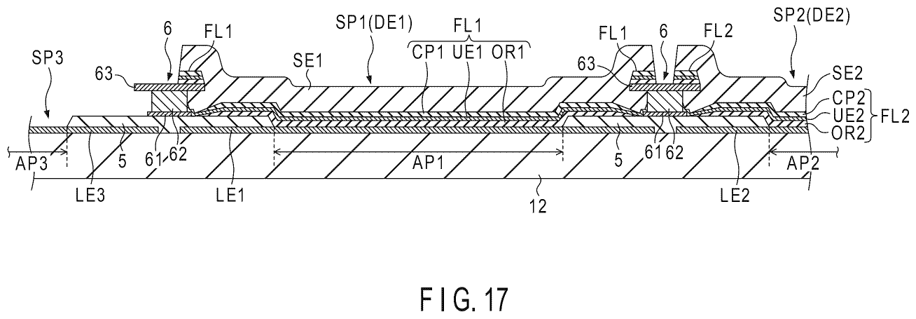

Process PR6 allows the acquisition of the following substrate. As shown in FIG. 17, in the substrate, the display element DE1 and the sealing layer SE1 are formed in subpixel SP1, and the display element DE2 and the sealing layer SE2 are formed in subpixel SP2, and neither a display element nor a sealing layer is formed in subpixel SP3.

The display element DE3 is formed by a procedure similar to the procedures of the display elements DE1 and DE2. Specifically, after process PR6, the organic layer OR3 which covers the lower electrode LE3 through the pixel aperture AP3, the upper electrode UE3 which covers the organic layer OR3 and the cap layer CP3 which covers the upper electrode UE3 are formed in order by vapor deposition, and further, the sealing layer SE3 which continuously covers the cap layer CP3 and the partition 6 is formed by CVD (process PR7).

The thin film FL3 including the organic layer OR3, the upper electrode UE3 and the cap layer CP3 is formed in at least the entire display area DA, is provided in subpixels SP1 and SP2 as well as subpixel SP3 and is also provided on the partition 6. The thin film FL3 is divided by the partition 6 having an overhang shape. The sealing layer SE3 is formed in the entire display area DA and continuously covers the thin film FL3 and the partition 6 without being divided by the partition 6.

After process PR7, the thin film FL3 and the sealing layer SE3 are patterned by wet etching and dry etching (process PR8). The flow of this patterning is similar to that of process PR4.

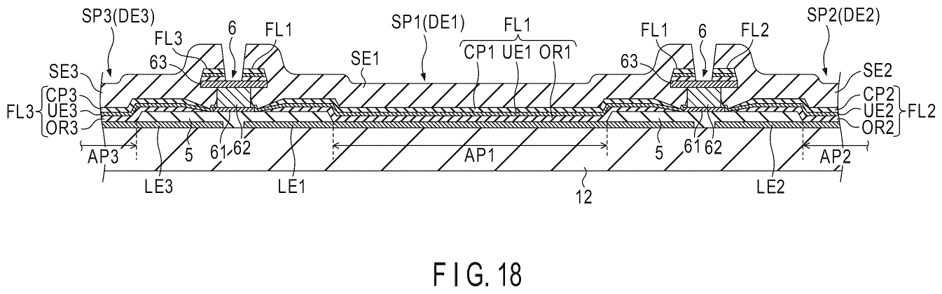

Process PR8 allows the acquisition of the following substrate. As shown in FIG. 18, in the substrate, the display element DE1 and the sealing layer SE1 are formed in subpixel SP1, and the display element DE2 and the sealing layer SE2 are formed in subpixel SP2, and the display element DE3 and the sealing layer SE3 are formed in subpixel SP3.

After the display elements DE1, DE2 and DE3 and the sealing layers SE1, SE2 and SE3 are formed, the resin layer 13, sealing layer 14 and resin layer 15 shown in FIG. 3 are formed in order (process PR9). By this process, the display device DSP is completed.

In the manufacturing method of the display device DSP of the embodiment explained above, the thin films FL1, FL2 and FL3 formed by vapor deposition are divided by the partition 6 having an overhang shape. Further, by covering these divided thin films FL1, FL2 and FL3 with the sealing layers SE1, SE2 and SE3, respectively, the display elements DE1, DE2 and DE3 which are individually sealed can be obtained. The partition 6 also functions as a line which supplies electricity to the upper electrodes UE1, UE2 and UE3.

Here, effects which are further obtained from the embodiment are explained with reference to FIG. 4. To satisfactorily divide the thin films FL1 and FL2 formed by vapor deposition by the partition 6, protrusion lengths D21 and D22 of the top portion 63 from the side surfaces F1 and F2 of the stem portion 62 need to be sufficiently long. However, if protrusion lengths D21 and D22 are excessively long, the material of the upper electrode UE1 or UE2 is not easily attached to the area located under the top portion 63 at the time of vapor deposition. Thus, if the bottom portion 61 does not protrude from the side surface F1 or F2 of the stem portion 62, there is a possibility that the contact between the upper electrodes UE1 and UE2 and the bottom portion 61 or the stem portion 62 is insufficient.

To the contrary, as shown in FIG. 4, when the end portions E11 and E12 of the bottom portion 61 protrude from the side surfaces F1 and F2, the upper electrodes UE1 and UE2 which are satisfactorily in contact with the bottom portion 61 can be formed while sufficiently assuring protrusion lengths D21 and D22 of the top portion 63. As a result, the conduction between the upper electrodes UE1 and UE2 and the partition 6 becomes satisfactory.

Moreover, in the structure in which the bottom portion 61 protrudes from the side surfaces F1 and F2, even if the bottom portion 61 is formed so as to be thin, the contact area of the upper electrodes UE1 and UE2 and the bottom portion 61 can be increased. However, if protrusion lengths D11 and D12 of the bottom portion 61 are excessively long, there is a possibility that undesired leak current flows between the organic layers OR1 and OR2 and the bottom portion 61 as the organic layers OR1 and OR2 are in contact with the bottom portion 61.

To solve this problem, each of protrusion lengths D11 and D12 could be determined in a range which is greater than thickness T of the bottom portion 61 and less than protrusion lengths D21 and D22. For example, as described above, each of protrusion lengths D11 and D12 should be desirably greater than or equal to 0.2 μm and less than or equal to 0.7 μm. More desirably, each of protrusion lengths D11 and D12 should be greater than or equal to 0.3 μm and less than or equal to 0.5 μm.

For example, when the stem portion 62 is formed of aluminum, there is a possibility that the surface of the stem portion 62 oxidizes before the formation of the upper electrodes UE1 and UE2. In this case, even if the upper electrodes UE1 and UE2 are in contact with the side surfaces F1 and F2, the conduction between the upper electrodes UE1 and UE2 and the stem portion 62 may become defective. To the contrary, when the bottom portion 61 is formed of a material which does not easily oxidize, such as titanium nitride, and further, the contact area of the bottom portion 61 and the upper electrodes UE1 and UE2 is made great like the embodiment, the upper electrodes UE1 and UE2 can be electrically connected to the partition 6 in a good manner.

It should be noted that the above effects which are explained while looking at the upper electrodes UE1 and UE2 and the partition 6 are also obtained with respect to the upper electrode UE3 and the partition 6. This configuration can prevent the defective conduction between the upper electrodes UE1, UE2 and UE3 and the partition 6 and improve the yield of the display device DSP.

All of the display devices and manufacturing methods thereof that can be implemented by a person of ordinary skill in the art through arbitrary design changes to the display device and the manufacturing method described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is

1. A display device comprising:
a lower electrode;
a rib comprising a pixel aperture which overlaps the lower electrode;
a partition which includes
a lower portion provided on the rib, and
a top portion provided on the lower portion;
an organic layer which covers the lower electrode through the pixel aperture and emits light based on application of voltage; and
an upper electrode which covers the organic layer and is in contact with the lower portion,
wherein
the lower portion includes
a conductive bottom portion provided on the rib, and
a stem portion provided between the bottom portion and the top portion,
the bottom portion and the top portion protrude from a side surface of the stem portion, and
a first protrusion length of the bottom portion from the side surface is greater than or equal to 0.2 μm and less than or equal to 0.7 μm.

2. The display device of claim 1, wherein
the first protrusion length is greater than or equal to 0.3 μm and less than or equal to 0.5 μm.

3. The display device of claim 1, wherein
the first protrusion length is less than a second protrusion length of the top portion from the side surface.

4. The display device of claim 1, wherein the bottom portion is thinner than the stem portion.

5. The display device of claim 1, wherein
the first protrusion length is greater than a thickness of the bottom portion.

6. The display device of claim 1, wherein
the bottom portion is formed of titanium nitride.

7. The display device of claim 6, wherein
the stem portion is formed of aluminum.

8. The display device of claim 1, wherein
the top portion comprises a first top layer, and a second top layer provided on the first top layer.

9. The display device of claim 8, wherein
the first top layer is formed of titanium, and
the second top layer is formed of ITO.

10. The display device of claim 1, further comprising a sealing layer which continuously covers the partition and a thin film including the organic layer and the upper electrode.

11. The display device of claim 10, wherein
the thin film further comprises an optical adjustment layer which covers the upper electrode, and
the optical adjustment layer is formed of a material which is different from the upper electrode and the sealing layers.

12. The display device of claim 10, wherein
the rib and the sealing layer are formed of inorganic insulating materials which are different from each other.

13. The display device of claim 1, wherein
the bottom portion includes
a lower surface in direct contact with the rib and
an upper surface opposing the lower surface, and
the upper electrode is in direct contact with the upper surface of the bottom portion.

14. A display device comprising:
a lower electrode;
a rib comprising a pixel aperture which overlaps the lower electrode;
a partition which includes
a conductive bottom portion provided on the rib,
a stem portion provided on the bottom portion,
a first top portion provided on the stem portion, and
a second top portion provided on the first top portion;
an organic layer which covers the lower electrode through the pixel aperture and emits light based on application of voltage; and
an upper electrode which covers the organic layer and is in contact with the bottom portion,
wherein
the bottom portion, the first top portion and the second top portion protrude from a side surface of the stem portion, and
a first protrusion length of the bottom portion from the side surface is less than a second protrusion length of the second top portion from the side surface.

15. The display device of claim 14, wherein
the first protrusion length is greater than or equal to 0.2 μm and less than or equal to 0.7 μm.

16. The display device of claim 14, wherein
the bottom portion is thinner than the stem portion.

17. The display device of claim 14, wherein
the first protrusion length is greater than a thickness of the bottom portion.

18. The display device of claim 14, wherein
the first top layer is formed of titanium, and
the second top layer is formed of ITO.

19. The display device of claim 14, wherein
the bottom portion, the stem portion, the first top portion, and the second top portion are stacked in a third direction, and
the stem portion overlaps the lower electrode in the third direction.

20. The display device of claim 14, wherein
the bottom portion, the stem portion, the first top portion, and the second top portion are stacked in a third direction, and
the bottom portion overlaps the lower electrode in the third direction.
